(19) United States
(12) Patent Application Publication
(10) Pub. No.: US 2024/0170061 A1
(43) Pub. Date: May 23, 2024

(54) HALIDE PEROVSKITE OPTICAL STORAGE AND MEMORY ARRAYS

(71) Applicant: NORTHWESTERN UNIVERSITY, Evanston, IL (US)

(72) Inventors: Chad A. Mirkin, Wilmette, IL (US); Minliang Lai, Evanston, IL (US); Donghoon Shin, Evanston, IL (US)

(21) Appl. No.: 18/517,238

(22) Filed: Nov. 22, 2023

Related U.S. Application Data
(60) Provisional application No. 63/427,504, filed on Nov. 23, 2022.

(51) Int. Cl. G11C 13/04; G03F 7/00

(52) U.S. Cl. CPC G11C 13/04; G03F 7/0005

(57) ABSTRACT

Hybrid organic-inorganic metal perovskites are utilized to generate optical switches that can be laser written in an ultra-fast and low-energy process.

### FIELD

The disclosure relates to halide perovskite optical storage and memory arrays and methods of making the same and using the same, in particular laser-writing, thermal-reset reversible processes for use thereof.

### BACKGROUND

The exponential growth of big data and artificial intelligence highly demands massive information storage and data processing. One emerging approach for ultra-high data capacity is optical techniques, including using optical non-linearity, super-resolution optical lithography, and multi-dimensional storage methods. However, these methods typically perform the optical writing with high energy consumption and at a slow speed. In addition, those methods are generally read-only or recordable (write-once), and thus not rewritable for data transfer and processing. To realize rewritable optical memories, two optical distinct states can be switched by a reversible “write-reset” process with fast speed. One promising candidate is phase change memory (PCM), which uses laser-induced heating to switch between amorphous and crystalline phases. One of the main challenges for optical PCMs is high beam intensity for the optical switch, generally accessible by high-power Femto- or picosecond pulse lasers. Consequently, an energy-efficient optical switch by continuous-wave lasers remains unexplored, which significantly limits the integration of current on-chip photonic technology. In addition, high-density PCM arrays most commonly rely on sophisticated and conventional lithography methods and are not suitable to be prepared via simple solution-phase routes.

### SUMMARY

A method of forming an optical switch comprising an organic-inorganic hybrid perovskite in accordance with the disclosure can include depositing at least one feature formed of a metal halide having the formula BX2 on to a substrate, exposing the feature to a vapor having a compound of formula AX to convert the metal halide to an organic-inorganic hybrid perovskite having the formula ABX3, wherein, A is one or more of methylammonium, butylammonium, formamidinium, phenethylamine, 3-(aminomethyl)piperidinium, 4-(aminomethyl)piperidinium, cesium, and rubidium, B is a metal cation, and X is a halogen.

An optical switch in accordance with the disclosure includes a hybrid organic-inorganic halide perovskite of the formula ABX₃, wherein A is one or more of methylammonium, butylammonium, formamidinium, phenethylamine, 3-(aminomethyl)piperidinium, 4-(aminomethyl)piperidinium, cesium, and rubidium, B is a metal cation, and X is a halogen, and wherein the hybrid organic-inorganic perovskite is capable of undergoing a change in photoluminescence from a first photoluminescence to a second photoluminescence upon exposure to a laser, an intensity of the second photoluminescence is less than an intensity of the first photoluminescence.

A method of optical writing in accordance with the disclosure includes providing a plurality of optical switches each comprising a hybrid inorganic-organic halide perovskite of the formula ABX₃; and performing an optical writing by exposing at least a portion of the plurality of optical switches to a laser excitation, wherein upon excitation with the laser the hybrid inorganic-organic halide perovskites undergoes partial photodecomposition and changes from having a first photoluminescence to having a second photoluminescence, an intensity of the second photoluminescence being less than an intensity of the first photoluminescence.

### BRIEF DESCRIPTION OF THE DRAWINGS

FIG. 1A is a schematic illustration of vapor conversion synthesis of (OIHPs) arrays from metal halide arrays (PbBr₂+FABr→FAPbBr₃).

FIG. 1B is an SEM image of pre-patterned PbBr₂ arrays.

FIG. 1C is an SEM image of FAPbBr₃ arrays after vapor conversion with FABr. The scale bars in B and C are 5 μm.

FIG. 1D is an SEM image and corresponding EDS mapping of a VC-PPL FAPbBr₃ particle. The scale bar in d is 1 μm.

FIG. 1E is an HR-TEM image of a VC-PPL FAPbBr₃ particle.

FIG. 1F is a dark-field optical micrograph of VC-PPL FAPbBr₃ patterns of Northwestern University “N” logo on a silicon substrate. The scale bar in f is 100 μm.

FIG. 1G is a fluorescence image of an “N” logo pattern (center), and SEM images of selective areas of the pattern. The scale bar in G is 5 μm.

FIG. 2A is a schematic illustration of photon-generated electron (e−)/hole (h+) assisted decomposition process.

FIGS. 2B and 2C are PL spectra and corresponding Raman spectra, respectively, of a FAPbBr₃ particle after different 473-nm laser power exposure.

FIG. 2D shows the relative intensity evolution of PL peak and Raman intensity as a function of laser power, The Inset is a scheme of relative portion of PbBr₂/FAPbBr₃ estimated from Raman signal change of u(CN) at ˜1110 cm⁻¹.

FIG. 3A shows PL intensity evolution before and after a short time CW laser exposure (405 nm, 0.735 mW, 800 ns per particle). The PL intensity dramatically decreased after laser writing.

FIG. 3B shows PL images before and after single-pulse femtosecond laser exposure. The optical writing was realized within single-pulse exposure (150 fs time width) at ˜11 pJ energy consumption.

FIG. 3C shows confocal PL images of patterns written by confocal laser (‘1’, ‘2’, ‘3’, ‘4’).

FIG. 3D shows binary coded data into the FAPbBr₃ arrays with PL bright and dark states to represent ‘1’ and ‘0’ respectively. The PL image shows “Hello, NU” with standard ASCII code.

FIG. 4A is a schematic illustration of laser-writing, thermal-reset reversible reactions in FAPbBr₃ arrays between PL-bright and PL-dark states (FAPbBr₃χPbBr₂+FABr).

FIG. 4B is a PL spectra of a FAPbBr₃ particle after writing-reset cycle (initial-write-reset). (inset) PL images of a FAPbBr₃ array during the cycle process (initial, laser writing particles in the center, thermal-reset with converting with FABr vapor.

FIG. 4C shows PL intensity, peak wavelength, and full-width at half-maximum (FWHM) of a FAPbBr₃ particle region during the 10 cycles.

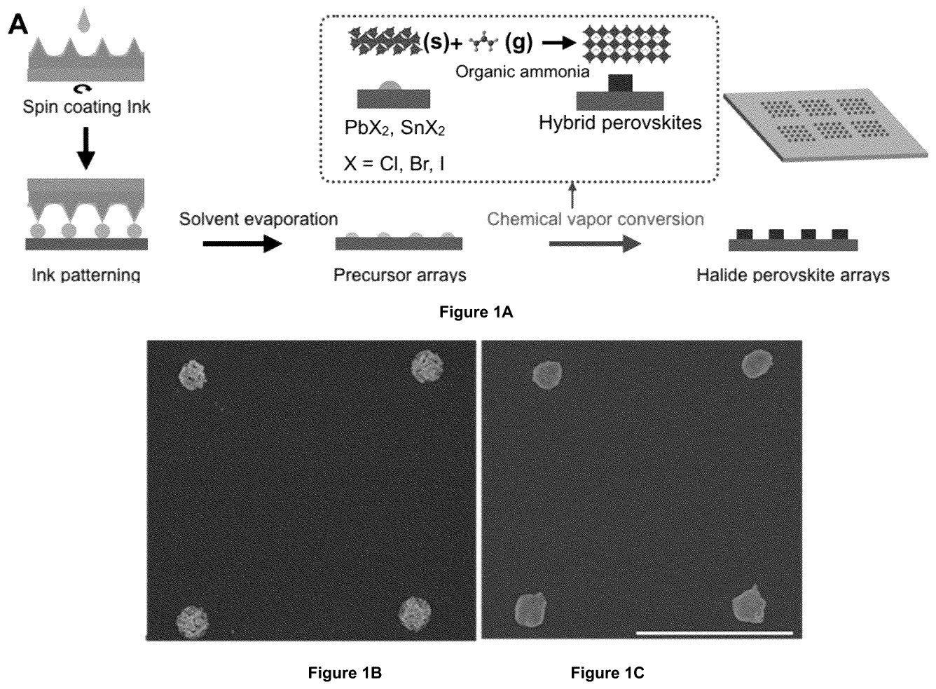

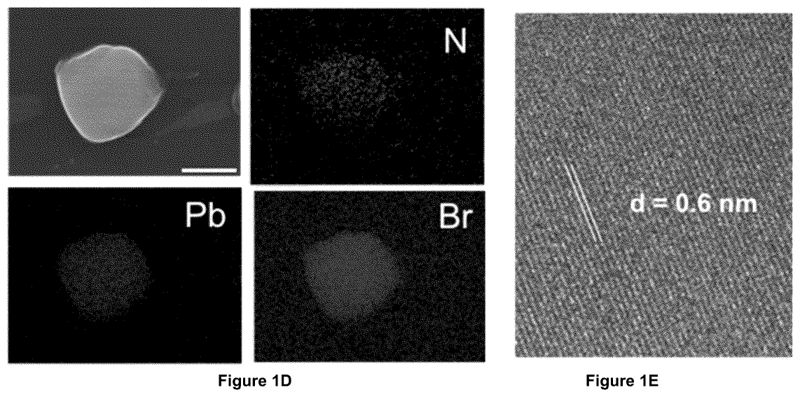

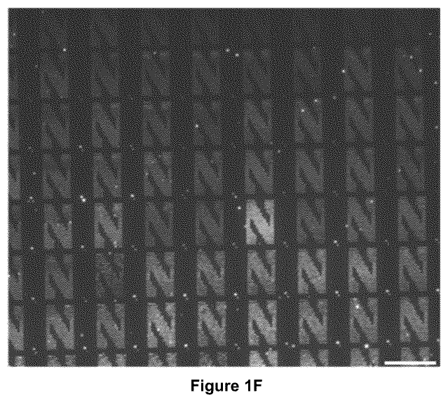

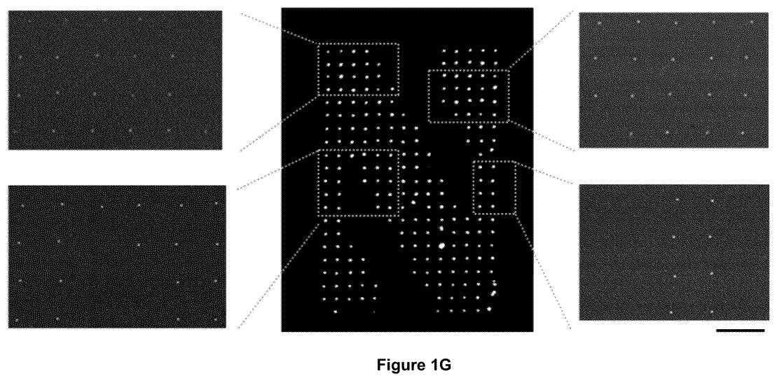

### DETAILED DESCRIPTION

Metal halide perovskites with a chemical formula ABX₃ is a new class of semiconductor materials with tunable optical properties and solution processibility. Their soft reconfigurable lattices make the structures and corresponding optical properties switchable by the external stimulus. Hybrid organic-inorganic halide perovskites (OIHPs) with susceptible organic A-sites have advantageously been found to be useful materials for optical switches with increased speed and energy efficiency compared to CsPbX₃ counterparts. CsPbX₃ optical patterns have been fabricated inside an oxide glass matrix by femtosecond laser heating, but the optical writing speed and energy consumption are not desired for optical memory. Additionally, the fabrication method used for conventional CsPbX₃ require high-temperature (˜1000°) C. to melt Cs, Pb, and X elements together with the glass medium. High temperatures are not required by the methods of the disclosure.

OIHP arrays in accordance with the disclosure can be formed using laser-writing, thermal-reset reversible reactions. Vapor conversion polymer pen lithography can be used to synthesize large-scale ABX₃ arrays converted from pre-patterned BX₂. As a laser-writing process, the OIHP arrays can be photo-decomposed to metal halides (BX₂) through laser exposure, resulting in a substantial decrease in photoluminescence (PL) intensity. Photo-decomposed arrays can then be reversely converted to OHIPs by reacting with Ax as the thermal-reset process to recover the PL intensity. This reversible reaction loop (ABX₃↔BX₂+AX) has a characteristic photoluminescence intensity switch as an optical writing-reset cycle. The photo-induced partial decomposition mechanism advantageously allows the optical writing to be achieved with ultra-low energy consumption and ultra-fast speed switch. For example, optical writing can be achieved with 11 pJ with a 150-fs pulse, even with the use of continuous-wave laser.

An optical switch in accordance with the disclosure is formed of a hybrid organic-inorganic halide perovskite. Optical switches in accordance with the disclosure are capable of undergoing partial photodecomposition, thereby converting the organic-inorganic halide perovskite from having a first photoluminescence intensity to a second photoluminescence intensity less than the first intensity. The conversion can be achieved through application of laser excitation with lower energy consumption and fast switch speeds. Exposure of the hybrid organic-inorganic metal perovskites to the laser results in partial photo-decomposition of the perovskites, which induces a detectable decrease in photoluminescence intensity. Patterns or arrays of hybrid organic-inorganic metal perovskites can be selectively written to provide an optical memory array encoded with any desired data.

The optical switches in accordance with the disclosure can be reversible written. For example, the laser excited optical switches having the second photoluminescence intensity can be restored to having the first photoluminescence intensity through thermal vapor conversion. That is the partially photo-decomposed optical switch can be exposed to a vapor comprising a compound of formula AX to be restored to the non-decomposed state. Repeated cycles of writing and reset can be performed on the optical switches of the disclosure.

A method of forming an optical switch in accordance with the disclosure can include depositing metal halides having the structure BX₂ on to a substrate. The metal halides can be nanoparticles, for example. The metal halides can be deposited in arrays or any desired pattern. For example, polymer pen lithography can be used to deposit the metal halides in a patterned array. For example, the metal halides can be formed on the substrate using evaporative-crystallization polymer pen lithography.

The metal halides are then exposed to a vapor having a compound with the structure AX to convert the metal halides to hybrid organic-inorganic hybrid perovskites having the formula ABX₃.

The optical switches of the disclosure comprise a hybrid organic-inorganic halide perovskite having the formula ABX₃. The optical switches formed form the hybrid organic-inorganic halide perovskites can be pre-patterned on a substrate. For example, a substrate can contain an array of optical switches.

In formula ABX₃, A can be one or more of methylammonium, butylammonium, formamidinium, phenethylamine, 3-(aminomethyl)piperidinium, 4-(aminomethyl)piperidinium, cesium, and rubidium.

B is a metal cation. For example, B can be one or more of lead, tin, europium, and germanium.

X is a halogen. For example, X can be one or more of I, Br, CI, F and At.

The optical switches of the disclosure can be formed of hybrid organic-inorganic metal perovskites having a feature size of about 10 microns to about 50 nanometers. The optical switches can be advantageously arranged in any desired pattern and can be selectively written in a desired pattern and/or to encode desired data using methods of the disclosure.

In the methods of making hybrid inorganic-organic metal perovskites in accordance with the disclosure, thermal vapor conversion of the metal halides can be performed by exposing the metal halides to a vapor generated by heating a powder comprising a compound of structure AX dissolved in an organic ammonia.

The metal halides can be exposed to the vapor for a time of about 10 s to about 10 hours. The metal halides can be exposed to a temperature of about 100° C. to about 200° C. during the thermal vapor conversion.

It has advantageously been found that the optical switches of the disclosure can allow for ultra-low energy and ultra-fast writing of the optical switches through laser excitation. The laser can have a power of about 10 pW to about 10 mW. The laser exposure time can be about 100 femtoseconds to about 100 seconds.

The laser exposure time can be down to single-pulse duration of about 50-femto seconds to about 150-Femto seconds. The methods of the disclosure can advantageously allow for use of low-power (˜0.5 mW) and ultrashort (800 nanoseconds) and continuous-wave lasers. Current optical memories have to rely on a pulse laser setup, or very high-power (>100 mW), long-exposure (>10 s) continuous-wave laser.

The optical switches, after writing are also capable of being reset by exposing the optical switches comprising the at least a portion of partially photo-decomposed hybrid inorganic-organic halide perovskites to a vapor having a compound of formula AX. The vapor restores the partially photo-decomposed hybrid organic-inorganic metal perovskites to the ABX₃ structure, thereby also restoring the photoluminescence to the first intensity.

Writing and reset of the optical switches can be performed any number of cycles. For example, it was observed that ten cycles could be performed without degradation of the optical switches.

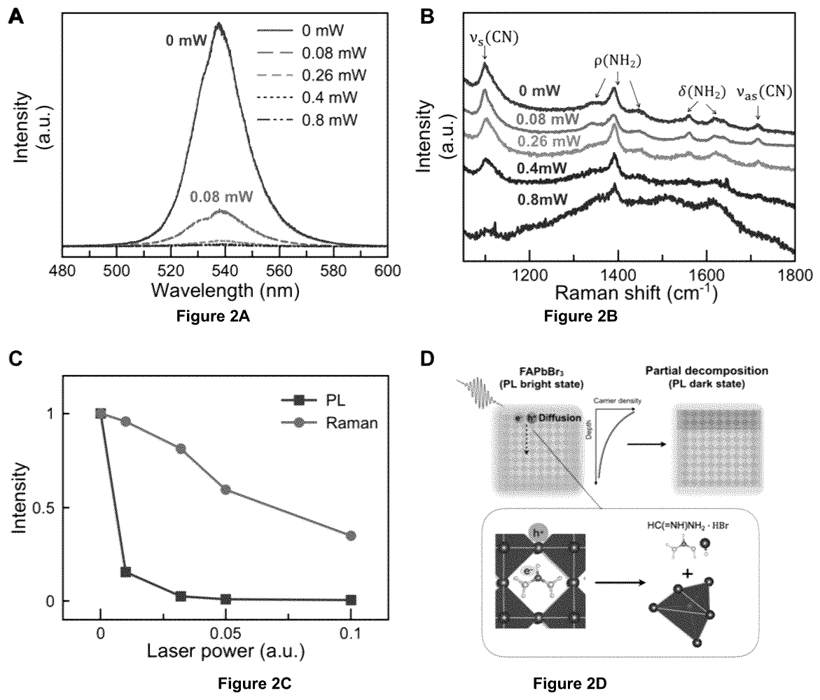

By way of example, a confocal continuous-wave laser was used to achieve optical writing in individual FAPbBr₃ particles. The evolution of PL spectra was collected when a FAPbBr₃ particle was exposed under different laser power (FIG. 2A). To monitor the correlated degree of decomposition (FAPbBr₃→PbBr₂), the spectra evolution of FA Raman active modes was measured. Although a significant decrease in PL intensity occurred at 0.05 Pₘₐₓ in FIG. 2A, the decomposition (FAPbBr₃→PbBr₂) should be minor as the intensity of characteristic Raman modes of FA⁺ (e.g. υ(CN) at ˜1110 cm⁻¹ and ˜1725 cm⁻¹) did not decrease much in FIG. 2B. As the laser power increased, the decomposition degree increased as Raman modes gradually disappeared. Taken together, the hysteresis between PL and Raman intensity evolution strongly suggests a partial photo-decomposition process (FIG. 2C), which can be further supported by Pb/Br ratio from the SEM-EDS spectrum.

Without intending to be bound by theory, it is believed that the photo-induced decomposition process is a results of a photochemical reaction among photon-generated electron (e)/hole (h⁺), HC(NH₂)₂⁺ and Br in the lattice, which could result in gas-phase HC(═NH)NH₂+HBr to escape the solid lattice (FIG. 2D). It was observed that high-temperature heating can induce (partial) decomposition of FAPbBr₃, as a loss of photoluminescence was observed after annealing the FAPbBr₃ array at 200° C. for 20 min. However, as shown in FIG. 2B, almost no change in photoluminescence intensity of FAPbBr₃ particles was observed during Raman acquisition after long-time exposure with a high-power 633-nm confocal laser. Thus, it is believed that a photochemical reaction results in the partial photodecomposition. Given that the photoluminescence efficiency of halide perovskite nanoparticles is mainly determined by their surface defects, partial decomposition is sufficient to achieve the optical switch to a photoluminescence dark state. This beneficially allows the optical switches to be optically written with low energy consumption. Additionally, the photochemical mechanism allows an ultrashort time to induce partial decomposition of the optical switches of the disclosure due to the ultrafast generation and migration of electron (e⁻)/hole (h⁺) in the lattice.

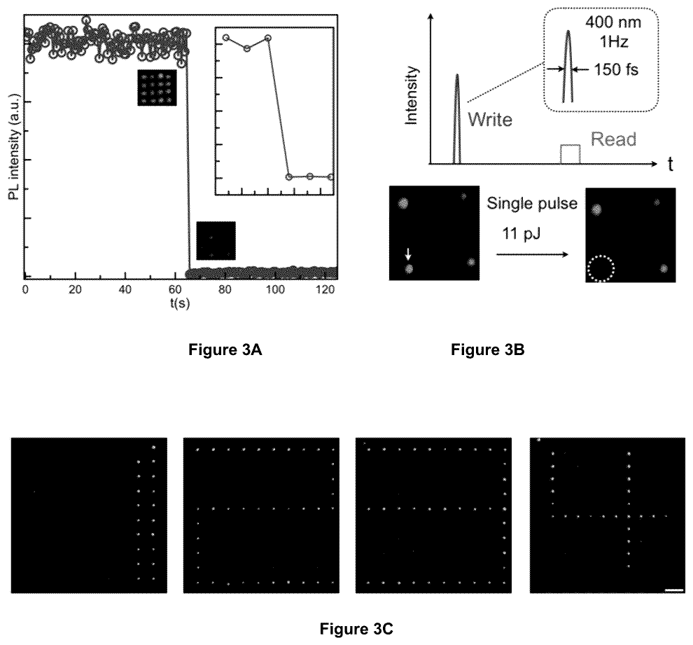

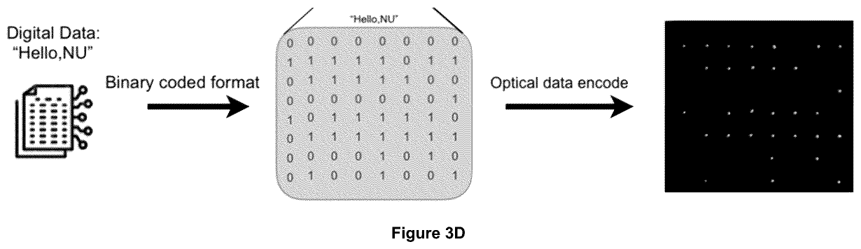

Time dependent change of photoluminescence under different laser (CW, 405 nm) power was investigated with fast confocal photoluminescence scanning. At a threshold power of 0.735 mW, the photoluminescence intensity quickly decayed to a dark state within the first scan frame, indicating a fast speed of optical writing. It was surprisingly found that optical writing could be achieved within 800 ns dwell time at 0.735 mW laser power. Referring to FIG. 3A, the written array remained in the photoluminescence dark state after this laser exposure. Optical writing was beneficially achieved with an ultra-fast writing speed of 800 ns and ultra-low energy consumption of about 0.6 nJ per bit using the CW laser. These values are significantly lower than conventional optical storage examples with CW lasers.

An optical writing process was also tested using a femtosecond pulse laser. The photoluminescence emission of FAPbBr₃ particles in accordance with the disclosure were capable of being imaged with an 800 nm laser (150 fs, 80 MHx) due to two-photon absorption and PL emission in FAPbBr₃. A fast and significant decay in photoluminescence intensity was observed using relatively low power of 1.8 mW and about 25 pJ per pulse. This two-photon testing confirmed the role of photon-generated electrons/holes in the compositions.

Optical writing was also achieved using a 400 nm laser (150 fs) with a pulse picker to tune the repetition rate from 200 kHz to 1 Hz. Referring to FIG. 3B, the laser writing was evaluated by directly imaging the particles before and after different pulses. Single-pulse (150 fs) optical writing with an ultra-low energy consumption of approximately 11 pJ was achieved.

The optical switches of the disclosure beneficially provide significant improvement in data writing and consumption of energy as compared to prior known optical switches, such as Cs-based perovskites in glass mediums using a heat-induced writing process with a femtosecond pulse laser irradiation. The writing process of the disclosure can be achieved with an energy-efficient single-pulsed process, which can enable high-efficiency optical memory and data processing with an ultrashort light pulsed, comparable to state-of-the-art optical memories.

Non-volatile optical memories can be generated using patterning of arrays of the hybrid organic-inorganic metal perovskites of the disclosure. FIG. 3C illustrates different patterns written on 10×10 arrays of FAPbBr₃ perovskites. Analogous to electronics, data can be stored with “1” or “0” optically in the arrays. Referring to FIG. 3D, the digital information “Hello, NU” was successfully encoded based on standard ASCII code. The optical data showed excellent stability under different conditions. The photoluminescence contrast of the encoded pattern was observed to be stable in ambient conditions at room temperature for over 30 days, and even further with annealing at 80° C. for 12 hours. This stability makes the optical data arrays able for practice use in typical environments for which optical memories are used. Further, the arrays were found to be non-volatile when the written laser was off. Additional stability enhancement could also be achieved through application of encapsulating or protective layers, such as organic polymer layers.

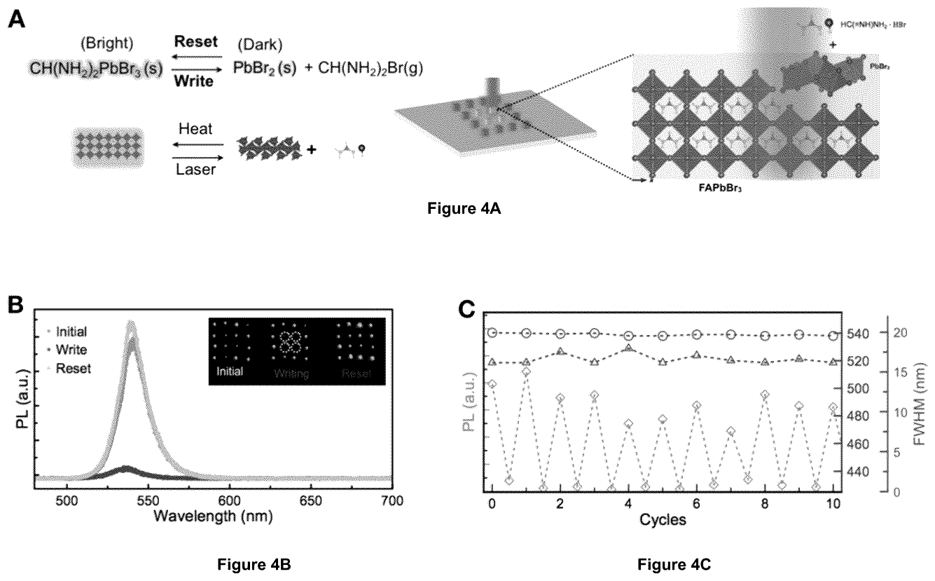

The optical switches of the disclosure can be rewritable using laser writing to optically write and then thermal vapor conversion to reset the optical switches. Referring to FIG. 4A, a rewritable process of FAPbBr₃ arrays is shown. FIG. 4B shows that the photoluminescence intensity of laser-written particle was recovered after the vapor conversion reset process. In FIG. 4B, this was shown by both photoluminescence imaging and spectrum with 4×4 array. Referring again to FIG. 4A, the reset particles maintained good morphology after the thermal vapor reset process.

Referring to FIG. 4C, rewriting was achieved over multiple cycles with stability being maintained over the cycles. In FIG. 4C, the FAPbBr₃ arrays were written and reset over ten repeated cycles.

### EXAMPLES

Synthesis of PbBr₂ Arrays. PbBr₂ arrays were synthesized by evaporation-crystallization polymer pen lithography (EC-PPL). The pyramidal-shaped-polymer pen arrays were fabricated based on a published protocol using h-polydimethylsiloxane (h-PDMS, Gelest). The pen array was mounted onto the XYZ motorized piezo scanner of a desktop nanopatterning instrument (TERA-Fab M series, TERA-print, LLC). The pen array was finely leveled parallel to the substrate with two piezo actuators before patterning. The pen array was removed from the instrument, treated with O₂ plasma, and then spin-coated with the ink at a spin speed of 3,000 rpm for 1 min or less depending on the type of ink precursor used. The ink was prepared by fully dissolving PbBr₂ in a dimethyl sulfoxide (DMSO) solvent. The ink concentration was varied accordingly to tune the PbBr₂ particle size. The inked pen array in the instrument was brought in contact with the substrate for a few seconds and retracted from the substrate to deliver small nanoreactors. The PbBr₂ particle size could be also tuned by extension length (0-8 μm from a contact point against the substrate). Nanoreactors of the ink was formed on the substrate after retraction of the pen array, and these droplets were allowed to evaporate under ambient conditions to form individual PbBr₂ particles.

Vapor-conversion process. The substrate with pre-patterned PbBr₂ arrays was placed on the bottom of 20-ml glass vial. Formamidine bromide (FABr) powder was deposited surrounding the PbBr₂ arrays on the bottom of a 20-ml glass vial. The glass vial was then capped and heated on a hot plate with a temperature controller set at about 150° C. to about 180 ºC. The vapor was formed due to the sublimation of FABr powders within the enclosed vial. Heating was performed for 1 hour to ensure the complete conversion from PbBr₂ to FAPbBr₃. Different organic ligands were used to prepare different compositions, including formamidine iodine (FAI), methylamine bromide (MABr), methylamine choline (MACI), butylamine bromide (BABr), butylamine iodine(BAI).

CW laser writing. High speed laser writing was preformed using a scanning confocal microscope (Lecia SP8). The optical writing parameters were adjusted to a short scan dwell time (exposure time) of 800 ns for each particle/pixel. The corresponding consumption of energy for each pixel was calculated with exposure time×laser power. Much lower power was used to read the photoluminescence before and after laser writing.

Single-pulse laser writing. An excitation wavelength of 400 nm was used from the second harmonic of 800 nm (˜150 fs, 250 kHz). The repetition rate was tuned with a pulse picker from 250 kHz down to 1 Hz. The laser power was measured with a power meter. The single-pulse laser writing was performed with manual control of the shutter to ensure the targeted particle was exposed by only a single pulse.

Raman measurement. The Raman spectra were performed with a confocal Raman setup (LabRAM HR Evolution, Horiba) with an optical objective (100×, NA=0.9) with 633-nm laser excitation. High-resolution photoluminescence (HRPL) was performed on a modified confocal Raman spectrometer, LabRAM HR Evolution (Horiba), with an excitation wavelength of 473 nm at room temperature.

Structural characterizations. The morphology and size distribution of all the crystals was imaged by scanning electron microscopy (SEM) on Hitachi SU8030. The energy-dispersive X-ray spectroscopy (EDS) was based on a silicon drift detector (SDD) (X-MaxN, Oxford Instruments) equipped on a Hitachi SU8030. Transmission electron microscopy (TEM) was performed on a JEOL ARM200CF equipped with a cFEG operated at 200 kV.

PL lifetime measurements. The PL lifetime measurements were performed using a 20×, 0.55 N.A. air objective with the Leica DiveB Sp8 Multiphoton confocal laser scanning microscope. The excitation wavelength is 800 nm from a Physics Mai Tai tunable laser (690-1040 nm). The lifetime decay is collected and analyzed by the Leica X software.

The foregoing description is given for clearness of understanding only, and no unnecessary limitations should be understood therefrom, as modifications within the scope of the disclosure may be apparent to those having ordinary skill in the art.

All patents, patent applications, government publications, government regulations, and literature references cited in this specification are hereby incorporated herein by reference in their entirety. In the case of conflict, the present description, including definitions, will control.

Throughout the specification, where the compounds, compositions, methods, and/or processes are described as including components, steps, or materials, it is contemplated that the compounds, compositions, methods, and/or processes can also comprise, consist essentially of, or consist of any combination of the recited components or materials, unless described otherwise. Component concentrations can be expressed in terms of weight concentrations, unless specifically indicated otherwise. Combinations of components are contemplated to include homogeneous and/or heterogeneous mixtures, as would be understood by a person of ordinary skill in the art in view of the foregoing disclosure.

### REFERENCES

1. S. W. Hell, J. Wichmann, Breaking the diffraction resolution limit by stimulated emission: stimulated-emission-depletion fluorescence microscopy. Opt. Lett. 19, 780-782 (1994).
2. J. Hanne et al., STED nanoscopy with fluorescent quantum dots. Nat. Commun. 6, 1-6 (2015).
3. P. Zijlstra, J. W. M. Chon, M. Gu, Five-dimensional optical recording mediated by surface plasmons in gold nanorods. Nature. 459, 410-413 (2009).
4. C. Ríos et al., Integrated all-photonic non-volatile multi-level memory. Nat. Photonics. 9, 725-732 (2015).
5. P. Li et al., Reversible optical switching of highly confined phonon-polaritons with an ultrathin phase-change material. Nat. Mater. 15 (2016), doi:10.1038/nmat4649.
6. C. Ríos et al., Integrated all-photonic non-volatile multi-level memory. Nat. Photonics. 9, 725-732 (2015).
7. J. S. Manser, J. A. Christians, P. V Kamat, Intriguing optoelectronic properties of metal halide perovskites. Chem. Rev. 116, 12956-13008 (2016).
8. H. Zhu et al., Lead halide perovskite nanowire lasers with low lasing thresholds and high quality factors. Nat. Mater. 14, 636-642 (2015).
9. Q. A. Akkerman et al., Tuning the optical properties of cesium lead halide perovskite nanocrystals by anion exchange reactions. J. Am. Chem. Soc. 137, 10276-10281 (2015).
10. G. Nedelcu et al., Fast Anion-Exchange in Highly Luminescent Nanocrystals of Cesium Lead Halide Perovskites (CsPbX₃, X=Cl, Br, I). Nano Lett. 15, 5635-5640 (2015).
11. J. Lin et al., Thermochromic halide perovskite solar cells. Nat. Mater. 17 (2018), doi:10.1038/s41563-017-0006-0.
12. J. A. Steele et al., Phase Transitions and Anion Exchange in All-Inorganic Halide Perovskites. Accounts Mater. Res. (2020), doi:10.1021/accountsmr.0c00009.
13. A. A. Zhumekenov, M. I. Saidaminov, O. F. Mohammed, O. M. Bakr, Stimuli-responsive switchable halide perovskites: Taking advantage of instability. Joule. 5, 2027-2046 (2021).
14. X. Huang et al., Reversible 3D laser printing of perovskite quantum dots inside a transparent medium. Nat. Photonics. 14, 82-88 (2020).
15. K. Sun et al., Three-dimensional direct lithography of stable perovskite nanocrystals in glass. Science (80-.). 375, 307-310 (2022).
16. X. Liu et al., Periodic organic-inorganic halide perovskite microplatelet arrays on silicon substrates for room-temperature lasing. Adv. Sci. 3, 1600137 (2016).
17. M. Chen et al., Three-Dimensional Perovskite Nanopixels for Ultrahigh-Resolution Color Displays and Multilevel Anticounterfeiting. Nano Lett. 21, 5186-5194 (2021).
18. G. Wang et al., Wafer-scale growth of large arrays of perovskite microplate crystals for functional electronics and optoelectronics. Sci. Adv. 1, e1500613 (2015).
19. F. Huo et al., Polymer pen lithography. Science (80-.). 321, 1658-1660 (2008).
20. J. S. Du et al., Halide perovskite nanocrystal arrays: Multiplexed synthesis and size-dependent emission. Sci. Adv. 6, eabc4959 (2020).
21. M. Lai, D. Shin, L. Jibril, C. A. Mirkin, Combinatorial Synthesis and Screening of Mixed Halide Perovskite Megalibraries. J. Am. Chem. Soc. 144, 13823-13830 (2022).
22. C. -K. Lin et al., Two-Step Patterning of Scalable All-Inorganic Halide Perovskite Arrays. ACS Nano (2020), doi:10.1021/acsnano.9b09685.
23. E. J. Juarez-Perez et al., Photodecomposition and thermal decomposition in methylammonium halide lead perovskites and inferred design principles to increase photovoltaic device stability. J. Mater. Chem. A. 6, 9604-9612 (2018).
24. S. Kundu, T. L. Kelly, In situ studies of the degradation mechanisms of perovskite solar cells. EcoMat. 2, e12025 (2020).
25. J. Xue, R. Wang, Y. Yang, The surface of halide perovskites from nano to bulk. Nat. Rev. Mater. 5, 809-827 (2020).
26. X. Zheng et al., Reducing defects in halide perovskite nanocrystals for light-emitting applications. J. Phys. Chem. Lett. 10, 2629-2640 (2019).
27. M. Gu, Q. Zhang, S. Lamon, Nanomaterials for optical data storage. Nat. Rev. Mater. 1 (2016), doi:10.1038/natrevmats.2016.70.
28. S. Lin et al., Optical Storage: A Photostimulated BaSi205: Eu2+, Nd3+ Phosphor-in-Glass for Erasable-Rewritable Optical Storage Medium (Laser Photonics Rev. 13 (4)/2019). Laser Photon. Rev. 13, 1970022 (2019).
29. K. Zheng et al., Rewritable optical memory through high-registry orthogonal upconversion. Adv. Mater. 30, 1801726 (2018).
30. T. Zou et al., High-speed femtosecond laser plasmonic lithography and reduction of graphene oxide for anisotropic photoresponse. Light Sci. Appl. 9, 1-11 (2020).
31. T. Alexoudi, G. T. Kanellos, N. Pleros, Optical RAM and integrated optical memories: a survey. Light Sci. Appl. 9, 1-16 (2020).

What is claimed is:

1. A method of forming an optical switch comprising an organic-inorganic hybrid perovskite, comprising:
depositing at least one feature formed of a metal halide having the formula BX₂ on to a substrate,
exposing the feature to a vapor having a compound of formula AX to convert the metal halide to an organic-inorganic hybrid perovskite having the formula ABX₃, wherein,
A is one or more of methylammonium, butylammonium, formamidinium, phenethylamine, 3-(aminomethyl)piperidinium, 4-(aminomethyl)piperidinium, cesium, and rubidium,
B is a metal cation, and
X is a halogen.

2. The method of claim 1, wherein B is selected from the group consisting of lead, tin, europium, and germanium, and/or X is one or more of I, Br, CI, F, and At.

3. The method of claim 1, wherein the vapor is formed by heating a powder comprising the compound of structure AX in an organic ammonia.

4. The method of claim 1, wherein feature is exposed to the vapor for about 10 seconds to about 10 hours.

5. The method of claim 1, wherein the feature is exposed to the vapor at a temperature of about 100° ° C. to about 200° C.

6. The method of claim 1, comprising depositing a plurality of features formed of the metal halide on the substrate, the plurality of features being deposited in a pattern.

7. The method of claim 1, wherein depositing the features comprises using polymer pen evaporation-crystallization polymer pen lithography.

8. The method of claim 1, where in the feature formed of the metal halides has a feature size of about 10 microns to about 50 nanometers.

9. The method of claim 1, wherein the hybrid organic-inorganic metal perovskites have a size of about 10 microns to about 50 nanometers.

10. An optical switch comprising a hybrid organic-inorganic halide perovskite of the formula ABX₃, wherein A is one or more of methylammonium, butylammonium, formamidinium, phenethylamine, 3-(aminomethyl)piperidinium, 4-(aminomethyl)piperidinium, cesium, and rubidium, B is a metal cation, and X is a halogen, and wherein the hybrid organic-inorganic perovskite is capable of undergoing a change in photoluminescence from a first photoluminescence to a second photoluminescence upon exposure to a laser, an intensity of the second photoluminescence is less than an intensity of the first photoluminescence.

11. The optical switch of claim 10, wherein the hybrid inorganic-organic halide perovskite is capable of a reversible change in photoluminescence, wherein after exposure to a laser renders the hybrid inorganic-organic halide perovskite to have the second photoluminescence, exposure to a vapor having a compound of formula BX₂ is capable of restoring the hybrid inorganic-organic halide perovskite to the first photoluminescence.

12. The optical switch of claim 10, wherein the laser power is about 10 pW to about 10 mW.

13. The optical switch of claim 10, wherein B is selected from the group consisting of lead, tin, europium, and germanium, an/or wherein X is one or more of I, Br, CI, F, and At

14. A method of optical writing, comprising:
providing a plurality of optical switches each comprising a hybrid inorganic-organic halide perovskite of the formula ABX₃; and
performing an optical writing by exposing at least a portion of the plurality of optical switches to a laser excitation, wherein upon excitation with the laser the hybrid inorganic-organic halide perovskites undergoes partial photodecomposition and changes from having a first photoluminescence to having a second photoluminescence, an intensity of the second photoluminescence being less than an intensity of the first photoluminescence.

15. The method of claim 14, further comprising preforming a reset by exposing the plurality of optical switches comprising the at least a portion of partially photo-decomposed hybrid inorganic-organic halide perovskites to a vapor having a compound of formula AX, wherein upon exposure to the vapor, the partially photo-decomposed hybrid inorganic-organic halide perovskites are restored to having the first photoluminescence.

16. The method of claim 18, comprising performing the optical writing and/or the reset one or more times.

17. The method of claim 14, wherein A is selected from the group consisting of methylammonium, butylammonium, formamidinium, phenethylamine, 3-(aminomethyl)piperidinium, 4-(aminomethyl)piperidinium, cesium, and rubidium, and/or B is selected from the group consisting of lead, tin, europium, and germanium

18. The method of claim 14, wherein X is one or more of I, Br, CI, F, and At.

19. The method of claim 14, wherein the vapor is formed by heating a powder comprising the compound of structure AX in an organic ammonia.

20. The method of claim 14, wherein the laser power is about 10 pW to about 10 mW.
